(19) United States
(12) Patent Application Publication
(10) Pub. No.: US 2012/0242524 A1
(43) Pub. Date: Sep. 27, 2012

(54) CURRENT SOURCE CELL AND DIGITAL-TO-ANALOG CONVERTER

(75) Inventor: Shigeo Imai, Yokohama-Shi (JP)

(73) Assignee: KABUSHIKI KAISHA TOSHIBA, Tokyo (JP)

(21) Appl. No.: 13/235,678

(22) Filed: Sep. 19, 2011

(30) Foreign Application Priority Data
Mar. 24, 2011 (JP) 2011-065894

(51) Int. Cl. H03M 1/66

(52) U.S. Cl. 341/150

(57) ABSTRACT

A digital-to-analog converter includes a current source cell that converts an input digital signal into an analog signal and outputs the analog signal. The digital-to-analog converter includes a first output terminal at which a first analog signal is output. The digital-to-analog converter includes a second output terminal at which a second analog signal is output, the second analog signal being complementary to the first analog signal. The digital-to-analog converter includes a first load resistor connected between a second potential and the first output terminal, the second potential being different from a first potential. The digital-to-analog converter includes a second load resistor connected between the second potential and the second output terminal.

### CROSS-REFERENCE TO RELATED APPLICATION

This application is based upon and claims the benefit of priority from the prior Japanese Patent Application No. 2011-065849, filed on Mar. 24, 2011, the entire contents of which are incorporated herein by reference.

### BACKGROUND

1. Field

Embodiments described herein relate generally to a current source cell converting an input digital signal into an analog signal and a digital-to-analog converter.

2. Background Art

A conventional current-controlled digital-to-analog converter receives a differential signal, which is a digital signal, and provides an output voltage, which is an analog signal. If the output voltage varies significantly, a differential transistor responsible for switching of the current path transits from the saturation region to the linear region and is activated.

Therefore, if the output voltage varies significantly, the impedance at the output terminal of the digital-to-analog converter also varies significantly. Accordingly, there is a problem that the analog signal (output signal) output from the output terminal is distorted.

### BRIEF DESCRIPTION OF THE DRAWINGS

FIG. 1 is a diagram showing an example of the configuration of a digital-to-analog converter 100 according to a first embodiment;

FIG. 2 is a diagram showing an example of a relationship between waveforms of the digital signals VDP and VDN input to the digital-to-analog converter 100 shown in FIG;

FIG. 3 is a diagram showing an example of the configuration of a digital-to-analog converter 200 according to the second embodiment;

FIG. 4 is a diagram showing an example of the configuration of a digital-to-analog converter 300 according to the third embodiment;

FIG. 5 is a diagram showing an example of the configuration of a digital-to-analog converter 400 according to the fourth embodiment; and

FIG. 6 is a diagram showing an example of the configuration of a digital-to-analog converter 500 according to the fifth embodiment.

### DETAILED DESCRIPTION

A current source cell according to an embodiment, includes includes a first switch element connected to the first potential at one end thereof. The current source cell a second switch element connected to another end of the first switch element at one end thereof, turning on/off of the second switch element being controlled to be complementary to turning on/off of the first switch element. The current source cell includes a first capacitor connected between another end of the second switch element and the second potential. The current source cell includes a first capacitance controlling switch element connected in parallel with the first capacitor between the another end of the second switch element and the second potential. The current source cell includes a current source that is connected to the first potential at one end thereof and outputs a constant current. The current source cell includes a first MOS transistor connected to another end of the current source at one end thereof, to the first output terminal at another end thereof, and to another end of the first switch element at a gate thereof. The current source cell includes a second capacitor connected between the gate of the first MOS transistor and a first fixed potential. The current source cell includes a third switch element connected to the first potential at one end thereof, turning on/off of the third switch element being controlled to be complementary to turning on/off of the first switch element. The current source cell includes a fourth switch element connected to another end of the third switch element at one end thereof, turning on/off of the fourth switch element being controlled to be complementary to turning on/off of the third switch element. The current source cell includes a third capacitor connected between another end of the fourth switch element and the second potential. The current source cell includes a second capacitance controlling switch element connected in parallel with the third capacitor between the another end of the fourth switch element and the second potential. The current source cell includes a second MOS transistor connected to the another end of the current source at one end thereof, to the second output terminal at another end thereof, and to the another end of the third switch element at a gate thereof. The current source cell includes a fourth capacitor connected between the gate of the second MOS transistor and the first fixed potential.

The first capacitance controlling switch element is turned off when the first MOS transistor is turned on and is turned on when the first MOS transistor is turned off. The second capacitance controlling switch element is turned off when the second MOS transistor is turned on and is turned on when the second MOS transistor is turned off.

### DETAILED DESCRIPTION OF THE INVENTION

In the following, embodiments will be described with reference to the drawings.

### First Embodiment

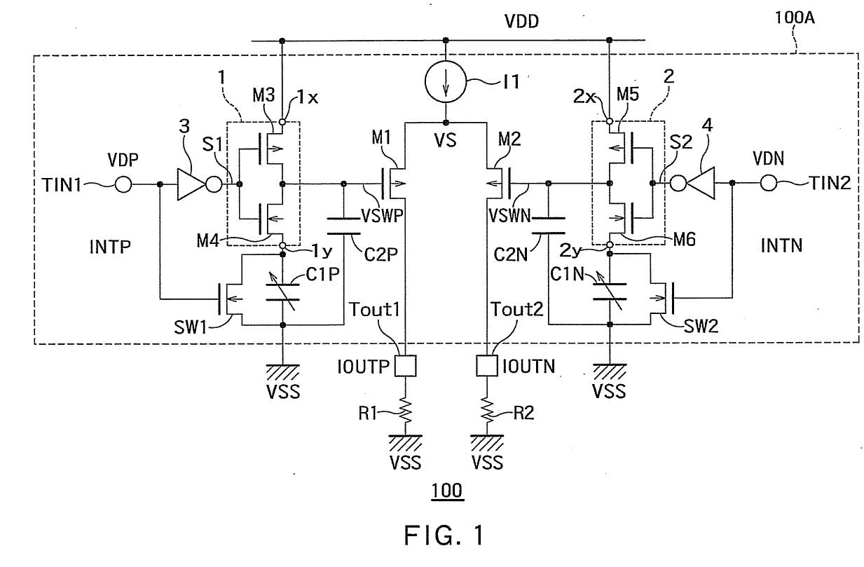

FIG. 1 is a diagram showing an example of the configuration of a digital-to-analog converter 100 according to a first embodiment.

In FIG. 1, a first potential is a power supply potential VDD, a second potential is a ground potential VSS, an MOS transistor of a first conductivity type is a p-MOS transistor, and an MOS transistor of a second conductivity type is an n-MOS transistor, for example. However, if the polarity of the circuit is inverted, the first potential is the ground potential VSS, the second potential is the power supply potential VDD, the MOS transistor of the first conductivity type is an n-MOS transistor, and the MOS transistor of the second conductivity type is a p-MOS transistor, for example.

As shown in FIG. 1, the digital-to-analog converter 100 converts input digital signals VDP and VDN into analog signals IOUTP and IOUTN and outputs the analog signals.

The digital-to-analog converter 100 includes a first inverter 1, a second inverter 2, a third inverter 3, a fourth inverter 4, a first input terminal TIN1, a second input terminal TIN2, a first capacitor C1P, a second capacitor C2P, a third capacitor C1N, a fourth capacitor C2N, a first capacitance controlling switch element SW1, a second capacitance controlling switch element SW2, a first MOS transistor of the first conductivity type (p-MOS transistor) Ml, a second MOS transistor of the first conductivity type (p-MOS transistor) M2, a current source I1, a first output terminal Tout1, a second output terminal Tout2, a first resistive load R1, and a second resistive load R2.

The first inverter 1, the second inverter 2, the third inverter 3, the fourth inverter 4, the first input terminal TIN1, the second input terminal TIN2, the first capacitor C1P, the second capacitor C2P, the third capacitor C1N, the fourth capacitor C2N, the first capacitance controlling switch element SW1, the second capacitance controlling switch element SW2, the first MOS transistor of the first conductivity type (p-MOS transistor) Ml, the second MOS transistor of the first conductivity type (p-MOS transistor) M2 and the current source I1 constitute a single current source cell 100A described earlier.

The first input terminal TIN1 is intended to receive a first input signal VDP, which is a digital signal.

The second input terminal TIN2 is intended to receive a second input signal VDN, which is a digital signal and is complementary to the first input signal VDP (i.e., has the opposite polarity to the first input signal VDP).

The third inverter 3 is connected to the first input terminal TIN1 at an input thereof and outputs a first signal S1, which is the first input signal VDP inverted.

The first inverter 1 is connected to an output of the third inverter 3 at an input thereof and to the first potential VDD at a first power supply terminal 1x. The first inverter 1 receives the first signal S1, which is a digital signal, and outputs a signal VSWP, which is the first signal S1 inverted.

As shown in FIG. 1, the first inverter 1 has a third MOS transistor of the first conductivity type (p-MOS transistor) M3, which serves as a first switch element, and a fourth MOS transistor of the second conductivity type (n-MOS transistor) M4, which serves as a second switch element, for example.

The third MOS transistor M3 is connected to the first power supply terminal 1x at one end (source) and to the gate of the first MOS transistor M1 at the other end (drain) and receives the first signal S1 at the gate thereof.

The fourth MOS transistor M4 is connected to the other end (drain) of the third MOS transistor M3 at one end (drain), to a second power supply terminal 1y at the other end (source) and to the gate of the third MOS transistor M3 at the gate thereof and receives the first signal S1 at the gate thereof.

That is, turning on/off of the fourth MOS transistor M4 serving as the second switch element is controlled to be complementary to turning on/off of the third MOS transistor M3 serving as the first switch element.

The first capacitor C1P is connected between the second power supply terminal 1y of the first inverter 1 and the second potential VSS, which differs from the first potential VDD.

The first capacitance controlling switch element SW1 is connected in parallel with the first capacitor C1P between the second power supply terminal 1y and the second potential VSS.

For example, the first capacitance controlling switch element SW1 is an MOS transistor of the second conductivity type (n-MOS transistor) that is connected in parallel with the first capacitor C1P between the second power supply terminal 1y and the second potential VSS and connected to the first input terminal TIN1 at the gate thereof.

The first MOS transistor M1 is connected to an output of the first inverter 1 at the gate thereof.

The second capacitor C2P is connected between the gate of the first MOS transistor M1 and a fixed potential (the second potential VSS in this example).

When the first input signal VDP is at a “High” level, the signal VSWP is also at the “High” level, so that the first MOS transistor M1 is in an off state. In this state, the first capacitance controlling switch element SW1 is in an on state. On the other hand, when the first input signal VDP is at a “Low” level, the signal VSWP is also at the “Low” level, so that the first MOS transistor M1 is in the on state. In this state, the first capacitance controlling switch element SW1 is in the off state.

That is, the first capacitance controlling switch element SW1 is controlled to be in the off state when the first MOS transistor M1 is in the on state and in the on state when the first MOS transistor M1 is in the off state.

As shown in FIG. 1, the fourth inverter 4 is connected to the second input terminal TIN2 at an input thereof and outputs a second signal S2, which is the second input signal VDN inverted.

The second inverter 2 is connected to an output of the fourth inverter 4 at an input thereof and to the first potential VDD at a third power supply terminal 2x. The second inverter 2 receives the second signal S2, which is a digital signal and is complementary to the first signal S1 (i.e., has an inverted phase with respect to the first signal S1), and outputs a signal VSWN, which is the second signal S2 inverted.

As shown in FIG. 1, for example, the second inverter 2 has a fifth MOS transistor of the first conductivity type (p-MOS transistor) M5, which serves as a third switch element, and a sixth MOS transistor of the second conductivity type (n-MOS transistor) M6, which serves as a fourth switch element.

The fifth MOS transistor M5 is connected to the third power supply terminal 2x at one end (source) and to the gate of the second MOS transistor M2 at the other end (drain) and receives the second signal S2 at the gate thereof.

That is, turning on/off of the fifth MOS transistor M5 serving as the third switch element is controlled to be complementary to turning on/off of the third MOS transistor M3 serving as the first switch element.

The sixth MOS transistor M6 is connected to the other end (drain) of the fifth MOS transistor M5 at one end (drain), to the fourth power supply terminal 2y at the other end (source), to the gate of the fifth MOS transistor M5 at the gate thereof, and receives the second signal S2 at the gate thereof.

That is, turning on/off of the sixth MOS transistor M6 serving as the fourth switch element is controlled to be complementary to turning on/off of the fifth MOS transistor M5 serving as the third switch element.

The third capacitor C1N is connected between the fourth power supply terminal 2y of the second inverter 2 and the second potential VSS.

The first capacitor C1P and the third capacitor C1N have the same electrical capacitance, for example.

The first capacitor C1P and the third capacitor C1N are variable capacitors having an adjustable electrical capacitance, for example. As described later, the electrical capacitance of the first capacitor C1P and the third capacitor C1N are adjusted according to the magnitudes of the maximum voltages at the first and second output terminals Tout1 and Tout2.

The second capacitance controlling switch element SW2 is connected in parallel with the third capacitor C1N between the fourth power supply terminal 2y and the second potential VSS.

For example, the second capacitance controlling switch element SW2 is an MOS transistor of the second conductivity type (n-MOS transistor) that is connected in parallel with the third capacitor C1N between the fourth power supply terminal 2y and the second potential VSS and connected to the second input terminal TIN2 at the gate thereof.

The second MOS transistor M2 is connected to an output of the second inverter 2 at the gate thereof.

The first MOS transistor M1 and the second MOS transistor M2 have the same size, for example.

The fourth capacitor C2N is connected between the gate of the second MOS transistor M2 and the fixed potential (the second potential VSS in this example).

The second capacitor C2P and the fourth capacitor C2N have the same electrical capacitance, for example.

When the second input signal VDN is at the “High” level, the signal VSWN is also at the “High” level, so that the second MOS transistor M2 is in the off state. In this state, the second capacitance controlling switch element SW2 is in the on state. On the other hand, when the second input signal VDN is at the “Low” level, the signal VSWN is also at the “Low” level, so that the second MOS transistor M2 is in the on state. In this state, the second capacitance controlling switch element SW2 is in the off state.

That is, the second capacitance controlling switch element SW2 is controlled to be in the off state when the second MOS transistor M2 is in the on state and in the on state when the second MOS transistor M2 is in the off state.

The current source I1 is connected to the first potential VDD at one end and to one ends (sources) of the first and second MOS transistors M1 and M2 at the other end, and outputs a constant current.

As shown in FIG. 1, the first output terminal Tout1 is connected to the other end (drain) of the first MOS transistor M1, and the first analog signal IOUTP is output at the first output terminal Tout1.

The first resistive load R1 is connected between the first output terminal Tout1 and the second potential VSS.

The second output terminal Tout2 is connected to the other end (drain) of the second MOS transistor M2, and the second analog signal IOUTN, which is complementary to the first analog signal IOUTP (i.e., has the inverted phase), is output at the second output terminal Tout2. That is, analog differential signals are output at the first and second output terminals Tout1 and Tout2.

The second resistive load R2 is connected between the second output terminal Tout2 and the second potential VSS.

Next, characteristics of the digital-to-analog converter 100 having the configuration described above will be discussed.

In order for the first and second MOS transistors M1 and M2 to operate in the saturation region, the following formula (1) has to be satisfied. In the formula (1), |Vds| represents the absolute value of the voltage between the drain and the source. |Vgs| represents the absolute value of the voltage between the gate and the source. |Vth| represents the absolute value of a threshold voltage.

|Vds|>|Vgs|−Nth| (1)

For example, if the first MOS transistor M1 shown in FIG. 1 satisfies the conditions expressed by the following formulas (2), (3) and (4) derived from the formula (1), the first MOS transistor M1 operates in the saturation region. In the formulas (2), (3) and (4), V1 represents the voltage at the first output terminal Tout1. VS represents a first fixed potential. VSWP represents a gate voltage.

|V1−VS|>|VSWP−VS|−|Vth| (2)

If V1<VS, and VSWP<VS, the formula (2) can be rewritten as the following formulas (3) and (4).

VS−V1>VS−VSWP−|Vth| (3)

V1<|VSWP|+|Vth| (4)

Therefore, when the voltage V1 at the first output terminal Tout1 is set high, the first MOS transistor M1 can operate in the saturation region if the gate voltage VSWP is set to be higher than the voltage V1.

The same description holds true for the operation of the second MOS transistor M2 in the saturation region.

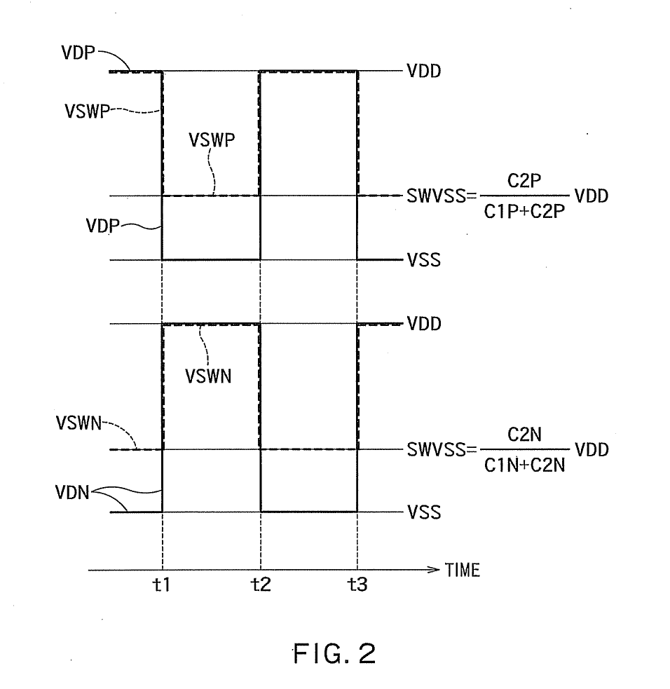

FIG. 2 is a diagram showing an example of a relationship between waveforms of the digital signals VDP and VDN input to the digital-to-analog converter 100 shown in FIG. 1 and waveforms of the signals VSWP and VSWN input to the gates of transistors M1 and M2

For the convenience of explanation, the electrical capacitances of the, first to fourth capacitors C1P, C2P, C1N and C2N are denoted by “C1P”, “C2P”, “C1N” and “C2N”, respectively.

As an example, an operation involving the first MOS transistor M1 will be particularly described.

As shown in FIG. 2, before a time t1, the first input signal VDP is at the “High” level (first potential VDD). Thus, the third MOS transistor M3 of the first inverter 1 is in the on state, and the fourth MOS transistor M4 is in the off state. The first capacitance controlling switch element SW1 is in the on state.

As a result, the second capacitor C2P is charged, and the gate voltage VSWP is at the “High” level (first potential VDD). Thus, the first MOS transistor M1 is in the off state. The first capacitor C1P discharges via the first capacitance controlling switch element SW1.

In this way, before the time t1, the first MOS transistor M1 is in the off state, and the first capacitance controlling switch element SW1 is in the on state.

Then, at the time t1, the first input signal VDP changes to the “Low” level (second potential VSS). As a result, the third MOS transistor M3 of the first inverter 1 is turned off, and the fourth MOS transistor M4 is turned on. The first capacitance controlling switch element SW1 is turned off.

As a result, the charge in the second capacitor C2P is distributed to the first capacitor C1P according to the electrical capacitance. As a result, the gate voltage VSWP changes to the “Low” level (potential SWVSS). The potential SWVSS is expressed by the formula (5) described below. As a result, the first MOS transistor M1 is turned on.

The gate voltage VSWP is set to be higher than the second potential VSS. The gate voltage VSWP at the “Low” level can be adjusted by adjusting the electrical capacitance of the first and second capacitors C1P and C2P as can be seen from the formula (5).

In this way, in a period between the time t1 and a time t2, the first MOS transistor M1 is in the on state, and the first capacitance controlling switch element SW1 is in the off state.

SWVSS=C2P/(C1P+C2P)*VDD (5)

Then, at the time t2, the first input signal VDP changes to the “High” level (first potential VDD). As a result, the third MOS transistor M3 of the first inverter 1 is turned on, and the fourth MOS transistor M4 is turned off. The first capacitance controlling switch element SW1 is turned on.

As a result, the second capacitor C2P is charged, and the gate voltage VSWP changes to the “High” level (first potential VDD). As a result, the first MOS transistor M1 is turned off. The first capacitor C1P discharges via the first capacitance controlling switch element SW1.

In this way, in a period between the time t2 and a time t3, the first MOS transistor M1 is in the off state, and the first capacitance controlling switch element SW1 is in the on state.

After that, the same operation is repeated. An operation involving the second MOS transistor M2 can be explained in the same way as the first MOS transistor with reference to FIG. 2.

As shown in FIG. 2, even if the “Low” level of the first and second input signals VDP and VDN is the ground potential, the “Low” level (minimum value) of the signals VSWP and VSWN is controlled to be the potentials SWVSS=C2P/(C1P+C2P)×VDD and SWVSS=C2N/(C1N+C2N)×VDD, respectively.

In this way, the gate voltages VSWP and VSWN are controlled so that the first and second MOS transistors M1 and M2 operate in the gate voltage saturation region even if the voltage of the output signals (analog signals) IOUTP and IOUTN is set high.

Thus, occurrence of a distortion in the output signals (analog signals) IOUTP and IOUTN is prevented.

In addition, the charging or discharging current flowing to or from the first to fourth capacitors in operation of the digital-to-analog converter 100 described above is considerably smaller than the current flowing in the case where a constant current is applied to a resistor to generate a bias voltage. Therefore, the current consumption can be reduced.

In short, the digital-to-analog converter according to the first embodiment can reduce the distortion in the output signal while reducing the current consumption.

### Second Embodiment

In the first embodiment, an example of the configuration of the digital-to-analog converter in which the second and fourth capacitors C2P and C2N are connected between the gate of the first MOS transistor M1 and the second potential (ground potential) VSS has been described.

In a second embodiment, an example of the configuration of the digital-to-analog converter in which the second and fourth capacitors C2P and C2N are connected between the gate of the first MOS transistor M1 and the first fixed potential VS will be described.

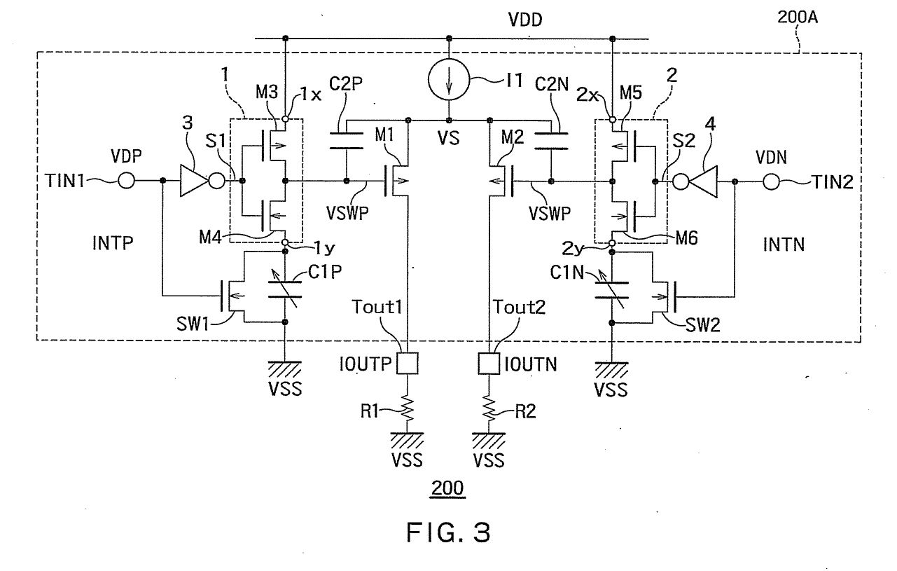

FIG. 3 is a diagram showing an example of the configuration of a digital-to-analog converter 200 according to the second embodiment. In FIG. 3, the same symbols as those in FIG. 1 denote the same parts as those in the first embodiment.

As shown in FIG. 3, the digital-to-analog converter 200 converts input digital signals VDP and VDN into analog signals IOUTP and IOUTN and outputs the analog signals.

As with the digital-to-analog converter 100 according to the first embodiment, the digital-to-analog converter 200 includes a first inverter 1, a second inverter 2, a third inverter 3, a fourth inverter 4, a first input terminal TIN1, a second input terminal TIN2, a first capacitor C1P, a second capacitor C2P, a third capacitor C1N, a fourth capacitor C2N, a first capacitance controlling switch element SW1, a second capacitance controlling switch element SW2, a first MOS transistor of a first conductivity type (p-MOS transistor) Ml, a second MOS transistor of the first conductivity type (p-MOS transistor) M2, a current source I1, a first output terminal Tout1, a second output terminal Tout2, a first resistive load R1, and a second resistive load R2.

The first inverter 1, the second inverter 2, the third inverter 3, the fourth inverter 4, the first input terminal TIN1, the second input terminal TIN2, the first capacitor C1P, the second capacitor C2P, the third capacitor C1N, the fourth capacitor C2N, the first capacitance controlling switch element SW1, the second capacitance controlling switch element SW2, the first MOS transistor of the first conductivity type (p-MOS transistor) M1, the second MOS transistor of the first conductivity type (p-MOS transistor) M2 and the current source I1 constitute a current source cell 200A.

As shown in FIG. 3, the second capacitor C2P is connected between the gate of the first MOS transistor M1 and a first fixed potential VS at the other end of the current source I1.

That is, the second capacitor C2P is connected between the gate of the first MOS transistor M1 and one end (source) of the first MOS transistor M1.

The fourth capacitor C2N is connected between the gate of the second MOS transistor M2 and the first fixed potential VS at the other end of the current source I1.

That is, the fourth capacitor C2N is connected between the gate of the second MOS transistor M2 and one end (source) of the second MOS transistor M2.

The remainder of the configuration of the digital-to-analog converter 200 is the same as the configuration of the digital-to-analog converter 100 according to the first embodiment.

The operation of the digital-to-analog converter 200 is the same as the operation of the digital-to-analog converter 100 according to the first embodiment.

That is, as in the first embodiment, the digital-to-analog converter according to the second embodiment can reduce the distortion in the output signal while reducing the current consumption.

### Third Embodiment

In a third embodiment, an example of the configuration of the digital-to-analog converter according to the first embodiment additionally provided with cascode MOS transistors will be described.

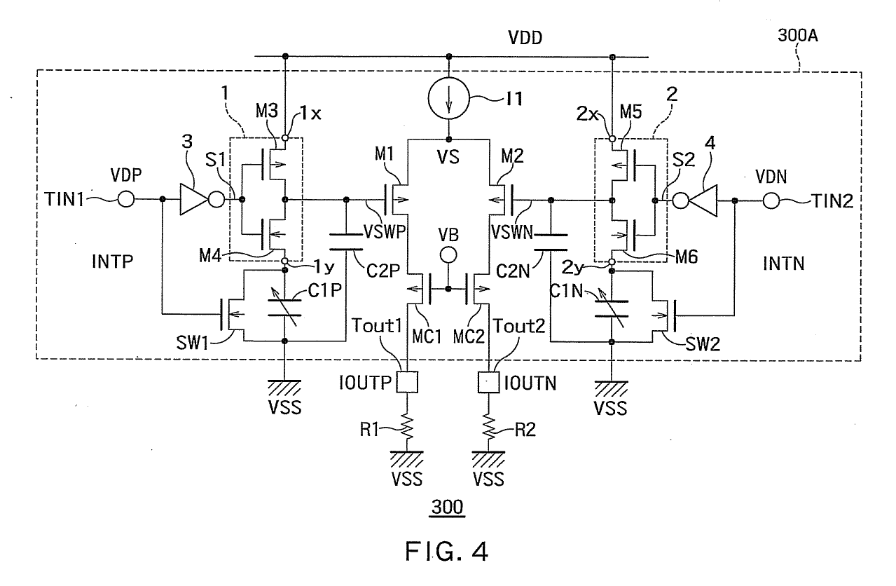

FIG. 4 is a diagram showing an example of the configuration of a digital-to-analog converter 300 according to the third embodiment. In FIG. 4, the same symbols as those in FIG. 1 denote the same parts as those in the first embodiment.

As shown in FIG. 4, the digital-to-analog converter 300 converts input digital signals VDP and VDN into analog signals IOUTP and IOUTN and outputs the analog signals.

As with the digital-to-analog converter 100 according to the first embodiment, the digital-to-analog converter 300 includes a first inverter 1, a second inverter 2, a third inverter 3, a fourth inverter 4, a first input terminal TIN1, a second input terminal TIN2, a first capacitor C1P, a second capacitor C2P, a third capacitor C1N, a fourth capacitor C2N, a first capacitance controlling switch element SW1, a second capacitance controlling switch element SW2, a first MOS transistor of a first conductivity type (p-MOS transistor) M1, a second MOS transistor of the first conductivity type (p-MOS transistor) M2, a current source I1, a first output terminal Tout1, a second output terminal Tout2, a first resistive load R1, and a second resistive load R2.

The digital-to-analog converter 300 further includes a first cascode-connecting MOS transistor of the first conductivity type (p-MOS transistor) MC1 and a second cascode-connecting MOS transistor of the first conductivity type (p-MOS transistor) MC2.

The first inverter 1, the second inverter 2, the third inverter 3, the fourth inverter 4, the first input terminal TIN1, the second input terminal TIN2, the first capacitor C1P, the second capacitor C2P, the third capacitor C1N, the fourth capacitor C2N, the first capacitance controlling switch element SW1, the second capacitance controlling switch element SW2, the first MOS transistor of the first conductivity type (p-MOS transistor) M1, the second MOS transistor of the first conductivity type (p-MOS transistor) M2, the first cascode-connecting MOS transistor of the first conductivity type (p-MOS transistor) MC1, the second cascode-connecting MOS transistor of the first conductivity type (p-MOS transistor) MC2 and the current source I1 constitute a current source cell 300A.

The first cascode-connecting MOS transistor MC1 is connected between the other end (drain) of the first MOS transistor M1 and the first output terminal Tout1 and is connected to a second fixed potential VB at the gate thereof.

The second cascode-connecting MOS transistor MC2 is connected between the other end (drain) of the second MOS transistor M2 and the second output terminal Tout2 and is connected to the gate of the first cascode-connecting MOS transistor MC1 (second fixed potential VB) at the gate thereof.

As described above, the digital-to-analog converter 300 differs from the digital-to-analog converter 100 according to the first embodiment in that the differential switch including the first and second MOS transistors M1 and M2 has a cascode configuration.

The remainder of the configuration of the digital-to-analog converter 300 is the same as the configuration of the digital-to-analog converter 100 according to the first embodiment.

The operation of the digital-to-analog converter 300 is the same as the operation of the digital-to-analog converter 100 according to the first embodiment.

That is, as in the first embodiment, the digital-to-analog converter according to the third embodiment can reduce the distortion in the output signal while reducing the current consumption.

In addition, since the cascode-connecting MOS transistors are inserted in the current source cell, the output resistance of the current source cell can be set higher.

### Fourth Embodiment

In a fourth embodiment, an example of the configuration of the digital-to-analog converter according to the second embodiment additionally provided with cascode MOS transistors will be described.

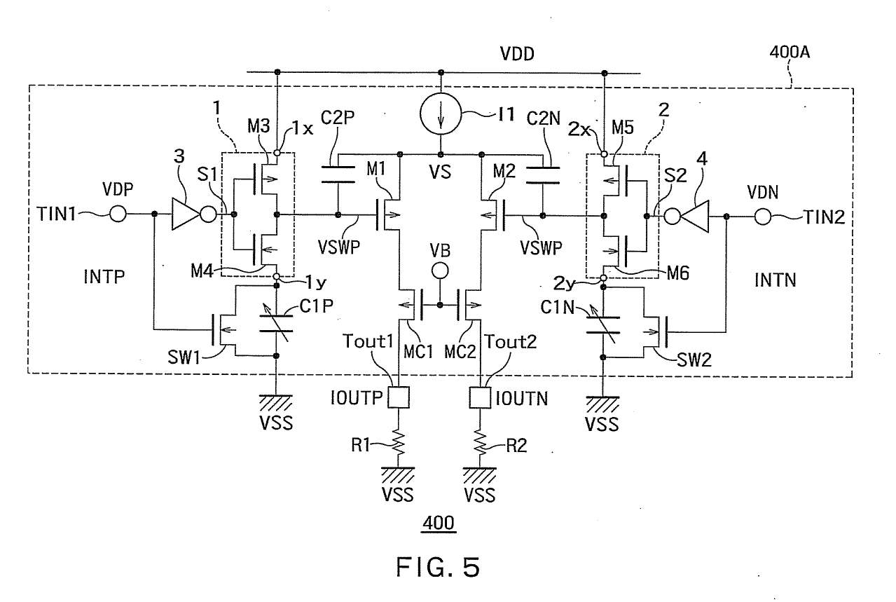

FIG. 5 is a diagram showing an example of the configuration of a digital-to-analog converter 400 according to the fourth embodiment In FIG. 5, the same symbols as those in FIG. 3 denote the same parts as those in the second embodiment.

As shown in FIG. 5, the digital-to-analog converter 400 converts input digital signals VDP and VDN into analog signals IOUTP and IOUTN and outputs the analog signals.

As with the digital-to-analog converter 200 according to the second embodiment, the digital-to-analog converter 400 includes a first inverter 1, a second inverter 2, a third inverter 3, a fourth inverter 4, a first input terminal TIN1, a second input terminal TIN2, a first capacitor C1P, a second capacitor C2P, a third capacitor C1N, a fourth capacitor C2N, a first capacitance controlling switch element SW1, a second capacitance controlling switch element SW2, a first MOS transistor of a first conductivity type (p-MOS transistor) M1, a second MOS transistor of the first conductivity type (p-MOS transistor) M2, a current source I1, a first output terminal Tout1, a second output terminal Tout2, a first resistive load R1, and a second resistive load R2.

The digital-to-analog converter 400 further includes a first cascode-connecting MOS transistor of the first conductivity type (p-MOS transistor) MC1 and a second cascode-connecting MOS transistor of the first conductivity type (p-MOS transistor) MC2.

The first inverter 1, the second inverter 2, the third inverter 3, the fourth inverter 4, the first input terminal TIN1, the second input terminal TIN2, the first capacitor C1P, the second capacitor C2P, the third capacitor C1N, the fourth capacitor C2N, the first capacitance controlling switch element SW1, the second capacitance controlling switch element SW2, the first MOS transistor of the first conductivity type (p-MOS transistor) M1, the second MOS transistor of the first conductivity type (p-MOS transistor) M2, the first cascode-connecting MOS transistor of the first conductivity type (p-MOS transistor) MC1, the second cascode-connecting MOS transistor of the first conductivity type (p-MOS transistor) MC2 and the current source I1 constitute a current source cell 400A.

The first cascode-connecting MOS transistor MC1 is connected between the other end (drain) of the first MOS transistor M1 and the first output terminal Tout1 and is connected to a second fixed potential VB at the gate thereof, and the second fixed voltage VB is set so that the first cascode-connecting MOS transistor MC1 and the second cascode-connecting MOS transistor MC2 operate in the saturation region.

The second cascode-connecting MOS transistor MC2 is connected between the other end (drain) of the second MOS transistor M2 and the second output terminal Tout2 and is connected to the gate of the first cascode-connecting MOS transistor MC1 (second fixed potential VB) at the gate thereof.

As described above, the digital-to-analog converter 400 differs from the digital-to-analog converter 200 according to the second embodiment in that the differential switch including the first and second MOS transistors M1 and M2 has a cascode configuration.

The remainder of the configuration of the digital-to-analog converter 400 is the same as the configuration of the digital-to-analog converter 200 according to the second embodiment.

The operation of the digital-to-analog converter 400 is the same as the operation of the digital-to-analog converter 200 according to the second embodiment.

That is, as in the second embodiment, the digital-to-analog converter according to the fourth embodiment can reduce the distortion in the output signal while reducing the current consumption.

In addition, since the cascode-connecting MOS transistors are inserted in the current source cell, the output resistance of the current source cell can be set higher.

### Fifth Embodiment

In the embodiments described above, the digital-to-analog converter has a single current source cell.

However, the digital-to-analog converter may have a plurality of stages of current source cells connected to each other.

In a fifth embodiment, an example of the configuration of the digital-to-analog converter according to the first embodiment including a plurality of stages of current source cells 100A will be described. Note that the current source cells of the digital-to-analog converter according to the fifth embodiment may be the current source cells 200A to 400A according to the second to fourth embodiments.

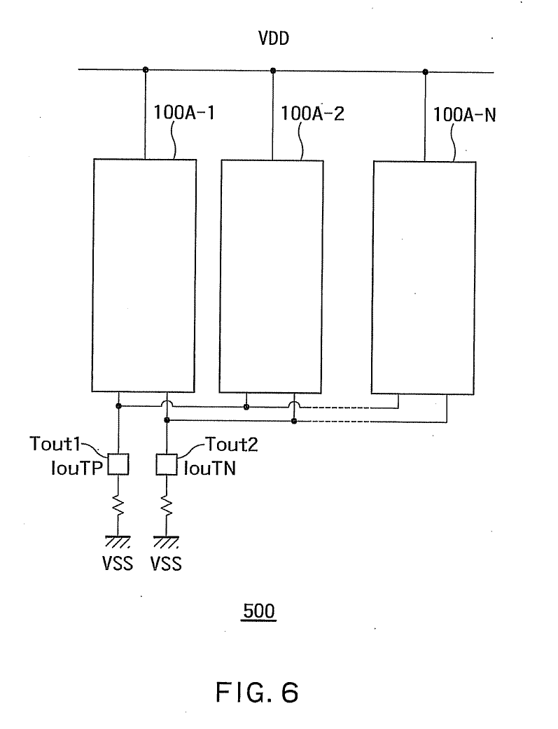

FIG. 6 is a diagram showing an example of the configuration of a digital-to-analog converter 500 according to the fifth embodiment. In FIG. 6, the same symbols as those in FIG. 1 denote the same parts as those in the first embodiment.

As shown in FIG. 6, the digital-to-analog converter 500 includes a plurality of current source cells 100A, a first output terminal Tout1, a second output terminal Tout2, a first load resistor R1, and a second load resistor R2.

The current source cells 100A are connected to the common first output terminal Tout1 and the common second output terminal Tout2.

The operation of the digital-to-analog converter 500 including the current source cells 100A-1, 100A-2, and 100A-N is the same way as the operation of the digital-to-analog converter 100 according to the first embodiment. The configuration of the current source cells are same one. However, the current value of the current source is different with respect to the current source cells. In the N-current source cells (N is an integer equal to or greater than 2), the current values of the current sources are weighted to 2^{N-1} LSB (Least Significant Bit).

That is, as in the first embodiment, the digital-to-analog converter according to the fifth embodiment can reduce the distortion in the output signal while reducing the current consumption.

In the embodiments described above, the second and fourth capacitors C2P and C2N are actually provided. However, the same effects and advantages can be provided if the second and fourth capacitors C2P and C2N are substituted by parasitic capacitances of the first and second MOS transistors M1 and M2.

In the embodiments described above, the current source cell is used in the digital-to-analog converter, and the other circuit. However, for example, the current source cell may be used in a current mode logic (CML) circuit.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A current source cell that converts an input digital signal into an analog signal and outputs the analog signal, comprising:
a first switch element connected to the first potential at one end thereof;
a second switch element connected to another end of the first switch element at one end thereof, turning on/off of the second switch element being controlled to be complementary to turning on/off of the first switch element;
a first capacitor connected between another end of the second switch element and the second potential;
a first capacitance controlling switch element connected in parallel with the first capacitor between the another end of the second switch element and the second potential;
a current source that is connected to the first potential at one end thereof and outputs a constant current;
a first MOS transistor connected to another end of the current source at one end thereof, to the first output terminal at another end thereof, and to another end of the first switch element at a gate thereof, the first output terminal outputting a first analog signal;
a second capacitor connected between the gate of the first MOS transistor and a first fixed potential;
a third switch element connected to the first potential at one end thereof, turning on/off of the third switch element being controlled to be complementary to turning on/off of the first switch element;
a fourth switch element connected to another end of the third switch element at one end thereof, turning on/off of the fourth switch element being controlled to be complementary to turning on/off of the third switch element;
a third capacitor connected between another end of the fourth switch element and the second potential;
a second capacitance controlling switch element connected in parallel with the third capacitor between the another end of the fourth switch element and the second potential;
a second MOS transistor connected to the another end of the current source at one end thereof, to the second output terminal at another end thereof, and to the another end of the third switch element at a gate thereof, the second output terminal outputting a second analog signal, and the second analog signal being complementary to the first analog signal; and
a fourth capacitor connected between the gate of the second MOS transistor and the first fixed potential, and
wherein
the first capacitance controlling switch element is turned off when the first MOS transistor is turned on and is turned on when the first MOS transistor is turned off, and
the second capacitance controlling switch element is turned off when the second MOS transistor is turned on and is turned on when the second MOS transistor is turned off.

2. The current source cell according to claim 1, wherein the first fixed potential is the second potential.

3. The current source cell according to claim 1, wherein the first fixed potential is a potential of the another end of the current source.

4. The current source cell according to claim 1, further comprising:
a first cascode-connecting MOS transistor connected between the another end of the first MOS transistor and the first output terminal; and
a second cascode-connecting MOS transistor connected between the another end of the second MOS transistor and the second output terminal,
wherein the first cascode-connecting MOS transistor and the second cascode-connecting MOS transistor operate in the saturation region.

5. The current source cell according to claim 4, wherein the first cascode-connecting MOS transistor and the second cascode-connecting MOS transistor are same conductive type, and a gate of the first cascode-connecting MOS transistor and a gate of the second cascode-connecting MOS transistor are connected to a second fixed potential.

6. The current source cell according to claim 1, wherein the first capacitor and the third capacitor are variable capacitors having an adjustable electrical capacitance.

7. The current source cell according to claim 1, wherein the first potential is a power supply potential, and the second potential is a ground potential.

8. The current source cell according to claim 1, wherein the second capacitor and the fourth capacitor have the same electrical capacitance.

9. The current source cell according to claim 1, wherein
the second capacitor is a parasitic capacitance of the first and second MOS transistor, and
the fourth capacitors is a parasitic capacitance of the second MOS transistor.

10. The current source cell according to claim 1, further comprising:
a first resistor connected to the first output terminal at one end thereof, and connected to the second potential at other end thereof, and
a second resistor connected to the second output terminal at one end thereof, and connected to the second potential at other end thereof.

11. A digital-to-analog converter, comprising:
a plurality of current source cells that converts an input digital signal into an analog signal and outputs the analog signal;
a first output terminal at which a first analog signal is output;
a second output terminal at which a second analog signal is output, the second analog signal being complementary to the first analog signal;
a first load resistor connected between a second potential and the first output terminal, the second potential being different from a first potential; and
a second load resistor connected between the second potential and the second output terminal,
wherein the plurality of current source cells each comprises:
a first switch element connected to the first potential at one end thereof;
a second switch element connected to another end of the first switch element at one end thereof, turning on/off of the second switch element being controlled to be complementary to turning on/off of the first switch element;
a first capacitor connected between another end of the second switch element and the second potential;
a first capacitance controlling switch element connected in parallel with the first capacitor between the another end of the second switch element and the second potential;
a current source that is connected to the first potential at one end thereof and outputs a constant current;
a first MOS transistor connected to another end of the current source at one end thereof, to the first output terminal at another end thereof, and to another end of the first switch element at a gate thereof;
a second capacitor connected between the gate of the first MOS transistor and a first fixed potential;
a third switch element connected to the first potential at one end thereof, turning on/off of the third switch element being controlled to be complementary to turning on/off of the first switch element;
a fourth switch element connected to another end of the third switch element at one end thereof, turning on/off of the fourth switch element being controlled to be complementary to turning on/off of the third switch element;
a third capacitor connected between another end of the fourth switch element and the second potential;
a second capacitance controlling switch element connected in parallel with the third capacitor between the another end of the fourth switch element and the second potential;
a second MOS transistor connected to the another end of the current source at one end thereof, to the second output terminal at another end thereof, and to the another end of the third switch element at a gate thereof; and
a fourth capacitor connected between the gate of the second MOS transistor and the first fixed potential, and
wherein
the first capacitance controlling switch element is turned off when the first MOS transistor is turned on and is turned on when the first MOS transistor is turned off, and
the second capacitance controlling switch element is turned off when the second MOS transistor is turned on and is turned on when the second MOS transistor is turned off.

12. The digital-to-analog converter according to claim 11, wherein the first fixed potential is the second potential.

13. The digital-to-analog converter according to claim 11, wherein the first fixed potential is a potential of the another end of the current source.

14. The digital-to-analog converter according to claim 11, further comprising:
a first cascode-connecting MOS transistor connected between the another end of the first MOS transistor and the first output terminal; and
a second cascode-connecting MOS transistor connected between the another end of the second MOS transistor and the second output terminal,
wherein the first cascode-connecting MOS transistor and the second cascode-connecting MOS transistor operate in the saturation region.

15. The digital-to-analog converter according to claim 14, wherein the first cascode-connecting MOS transistor and the second cascode-connecting MOS transistor are same conductive type, and a gate of the first cascode-connecting MOS transistor and a gate of the second cascode-connecting MOS transistor are connected to a second fixed potential.

16. The digital-to-analog converter according to claim 11, wherein the first capacitor and the third capacitor are variable capacitors having an adjustable electrical capacitance.

17. The digital-to-analog converter according to claim 11, wherein the first potential is a power supply potential, and the second potential is a ground potential.

18. The digital-to-analog converter according to claim 11, wherein the second capacitor and the fourth capacitor have the same electrical capacitance.

19. The digital-to-analog converter according to claim 11, wherein
the second capacitor is a parasitic capacitance of the first and second MOS transistor, and
the fourth capacitors is a parasitic capacitance of the second MOS transistor.

20. The digital-to-analog converter according to claim 11, wherein the plurality of current source cells are N-current source cells (N is an integer equal to or greater than 2), the current values of the current sources are weighted to 2^{N-1} LSB (Least Significant Bit).
